(19) United States
(12) Patent Application Publication
(10) Pub. No.: US 2012/0257363 A1
(43) Pub. Date: Oct. 11, 2012

(54) ELECTRONIC DEVICE WITH FIXING STRUCTURE

(75) Inventors: GUAN-DONG ZHAO, Shenzhen City (CN); XUE-FENG WAN, Shenzhen City (CN); ZHAO-YONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/283,297

(22) Filed: Oct. 27, 2011

(30) Foreign Application Priority Data
Apr. 6, 2011 (CN) 201110084787.0

(51) Int. Cl. H05K 5/00

(52) U.S. Cl. 361/759

(57) ABSTRACT

An electronic device includes a fixing structure to receive a circuit board. The fixing structure includes a first latching hook and a second latching hook spaced from each other. The circuit board defines a first latching slot corresponding to the second latching hook and a second latching slot corresponding to the first latching hook, at opposite ends of the circuit board. The first latching hook includes a first latching corner protrusion at the distal end of the first latching hook. The second latching hook includes a second latching corner protrusion at the distal end of the second latching hook. The circuit board is detachably fixed to the side wall, with the first latching hook engaged in the second latching slot, the second latching hook engaged in the first latching slot, and the first and second latching corner protrusions resisting any movement by the circuit board.

### BACKGROUND

1. Technical Field

The present disclosure relates to electronic devices, particularly to an electronic device with a fixing structure for detachably mounting a circuit board.

2. Description of Related Art

Many kinds of electronic devices, such as mobile phones, computers, and panel computers, have at least one circuit board. The circuit board may be fixed to the housing of the electronic device through a plurality of bolts. There requires at least two bolts to fix the circuit board firmly to the housing of the electronic device. However, it often needs more time to assemble or disassemble the circuit board.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the electronic device. Moreover, in the drawings like reference numerals designate corresponding parts throughout the several views. Wherever possible, the same reference numerals are used throughout the drawings to refer to the same or like elements of an embodiment.

FIG. 1 is an isometric view of a part of an embodiment of an electronic device.

FIG. 2 is an exploded, isometric view of the part of the electronic device of FIG. 1.

### DETAILED DESCRIPTION

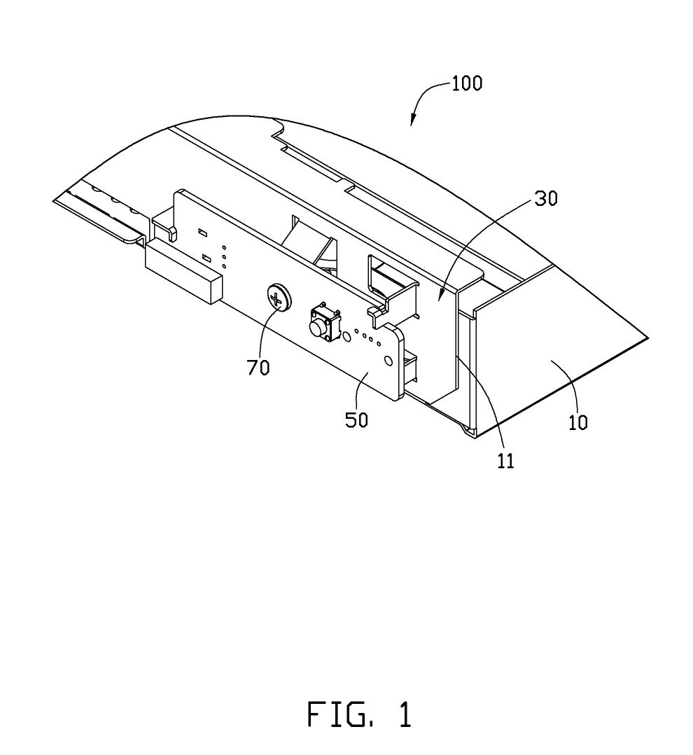

Referring to FIG. 1, an embodiment of an electronic device 100 includes a housing 10, a fixing structure 30, a circuit board 50 detachably fixed to the housing 10, and a fixing member 70. In the illustrated embodiment, the housing 10 includes a side wall 11. The fixing structure 30 is formed on the side wall 11. The circuit board 50 is detachably fixed to the fixing structure 30. The electronic device 100 may be a notebook computer, a desktop computer, a liquid crystal display, or other electronic device. In the illustrated embodiment, the electronic device 100 is a DVD video player.

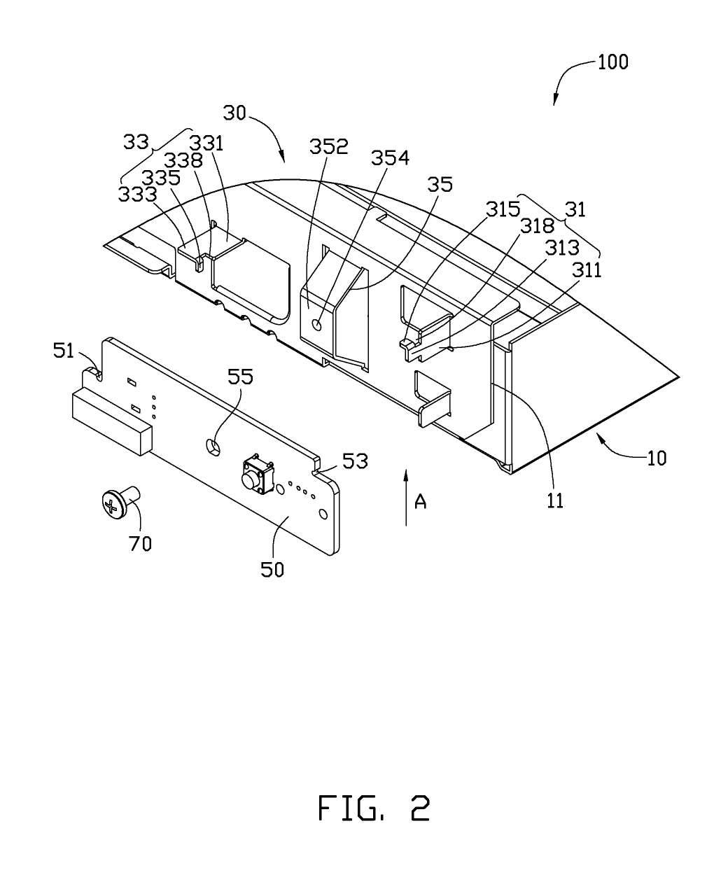

Referring to FIG. 2, the fixing structure 30 includes a first latching hook 31, a second latching hook 33 and a supporting member 35. In the illustrated embodiment, the latching hooks 31, 33 and the supporting member 35 all extend upward from the side wall 11 of the housing 10, and the latching hooks 31, 33 are located at opposite sides of the supporting member 35. The latching hooks 31, 33 are made of a resilient material such as metal or plastic.

The latching hook 31 includes a first main portion 311, a first latching arm 313, and a first latching corner protrusion 315. The first main portion 311 extends substantially perpendicularly upward from the side wall 11 of the housing 10. The latching arm 313 extends out from the distal end of the first main portion 311. The first latching corner protrusion 315 extends from the side of the first latching arm 313 adjacent to the distal end of the first latching arm 313 and is bent towards the latching hook 33. The first latching corner protrusion 315, the first latching arm 313 and the distal end of the first main portion 311 cooperatively define a latching groove 318 to latch with the circuit board 50.

The latching hook 33 is similar to the latching hook 31. The latching hook 33 includes a second main portion 331, a second latching arm 333, and a second latching corner protrusion 335. The second main portion 331 extends substantially perpendicularly upward from the side wall 11 of the housing 10. The second latching arm 333 extends out from the distal end of the second main portion 331. The latching corner protrusion 335 extends from the side of the second latching arm 333 adjacent to the distal end of the second latching arm 333 and is bent towards the inserting direction A of the circuit board 50. In the illustrated embodiment, the latching corner protrusions 315, 335 are perpendicular to each other to restrict any movement by the circuit board 50. The latching corner protrusion 335, the latching arm 333 and the distal end of the second main portion 331 cooperatively define a latching groove 338 to latch with the circuit board 50. In the illustrated embodiment, the length of the second main portion 331 is substantially equal to that of the first main portion 311.

The supporting member 35 is positioned at the side wall 11 between the first latching hook 31 and the second latching hook 33. In the illustrated embodiment, the supporting member 35 can be a substantially trapezoidal bridge plate. The supporting member 35 includes a supporting surface 352 parallel with the side wall 11 and a fixing hole 354 defined in the supporting surface 352. The fixing hole 354 is a threaded hole. The distance from the supporting surface 352 to the side wall 11 is substantially equal to the length of the first main portion 311 and the second main portion 331 to form a level and firm foundation for the circuit board 50.

The circuit board 50 can be a substantially rectangular plate. The circuit board 50 is detachably fixed to the side wall 11 of the housing 10. In the illustrated embodiment, the circuit board 50 is a USB circuit board. The circuit board 50 defines a first latching slot 51 corresponding to the second latching hook 33 and a second latching slot 53 corresponding to the first latching hook 31 at opposite ends of the circuit board 50. The circuit board 50 further defines a mounting hole 55 corresponding to the fixing hole 354 at about the center of the circuit board 50. The opening direction of the first latching slot 51 is opposite to the bending direction of the latching corner protrusion 335. The opening direction of the second latching slot 53 is opposite to the bending direction of the latching corner protrusion 315. The latching hooks 31, 33 engage in the latching slots 53, 51 to provide support from a plurality of different directions to fix the circuit board 50 to the side wall 11 with the latching corner protrusions 315, 335.

In the illustrated embodiment, the fixing member 70 is a screw corresponding to the fixing hole 354 of the supporting member 35. The circuit board 50 is fixed to the side wall 11 of the housing 10 via the fixing member 70 extending through the mounting hole 55 and the fixing hole 354.

During assembly of the electronic device 100, the circuit board 50 is positioned on the side wall 11 in direction A parallel to the side wall 11, with the latching hook 33 engaged in the latching slot 51, the latching hook 31 engaged in the latching slot 53, the mounting hole 55 communicating with the fixing hole 354, and the first and second latching corner protrusion 315, 335 resisting any movement by the circuit board 50. The fixing member 70 passes through the mounting hole 55 and is finally screwed in the fixing hole 354, such that the circuit board 50 is securely fixed to the side wall 11.

To disassemble the circuit board 50 from the side wall 11, the fixing member 70 may be unscrewed, and the circuit board 50 pushed in a direction opposite to that of direction A.

In the instant disclosure, the circuit board 50 is firmly fixed to the side wall 11 by means of the one fixing member 70 and the two latching hooks 31, 33. It is convenient to assemble or disassemble the circuit board 50. In alternative embodiments, the circuit board 50 can be firmly fixed to the side wall 11 through the two latching hooks 31, 33 as the two latching hooks 31, 33 are latched with the circuit board 50 in two opposite directions.

It is believed that the present embodiments and their advantages will be understood from the foregoing description, and it will be apparent that various changes may be made thereto without departing from the spirit and scope of the embodiments or sacrificing all of its material advantages.

What is claimed is:

1. An electronic device, comprising:
a housing comprising a side wall;
a fixing structure formed on the side wall of the housing, the fixing structure comprising a first latching hook and a second latching hook spaced from each other; and
a circuit board defining a first latching slot corresponding to the second latching hook and a second latching slot corresponding to the first latching hook at opposite ends of the circuit board, wherein the first latching hook comprises a first latching corner protrusion at the distal end of the first latching hook, the second latching hook comprises a second latching corner protrusion at the distal end of the second latching hook, the circuit board is detachably fixed to the side wall, with the first latching hook engaged in the second latching slot, the second latching hook engaged in the first latching slot, and the first and second latching corner protrusion resisting any movement by the circuit board.

2. The electronic device of claim 1, wherein the first latching hook further comprises a first main portion extending upward from the side wall of the housing, a first latching arm extending out from the distal end of the first main portion, and the first latching corner protrusion extends from the side of the first latching arm; the first latching corner protrusion, the first latching arm and the distal end of the first main portion cooperatively define a first latching groove, and the first latching corner protrusion engages in the second latching slot according to the first latching groove.

3. The electronic device of claim 2, wherein the second latching hook further comprises a second main portion extending upward from the side wall of the housing, a second latching arm extending out from the distal end of the first main portion, and the second latching corner protrusion extends from the side edge of the second latching arm; the second latching corner protrusion, the second latching arm and the distal end of the second main portion cooperatively define a second latching groove, the second latching corner protrusion engages in the first latching slot according to the second latching groove.

4. The electronic device of claim 1, wherein the first and second latching corner protrusions are perpendicular to each other.

5. The electronic device of claim 1, wherein the fixing structure further comprises a supporting member located between the first and second latching hooks to support the circuit board.

6. The electronic device of claim 5, wherein the supporting member comprises a supporting surface parallel to the side wall and a fixing hole defined in the supporting surface, the circuit board defines a mounting hole corresponding to the fixing hole, the electronic device further comprises a fixing member to fix the circuit board to the side wall via the fixing member extending through the mounting hole and the fixing hole.

7. The electronic device of claim 6, wherein the length of the first main portion, the length of the second main portion and the distance from the supporting surface to the side wall are respectively equal to each other.

8. The electronic device of claim 7, wherein the fixing member is a screw.

9. An electronic device, comprising:
a housing comprising a side wall;
a fixing structure formed on the side wall of the housing, the fixing structure comprising a supporting member defining a fixing hole, a first latching hook and a second latching hook;
a circuit board defining a first latching slot corresponding to the second latching hook and a second latching slot corresponding to the first latching hook at opposite ends of the circuit board; and
a fixing member, wherein the circuit board is detachably fixed to the side wall, with the first latching hook engaged in the second latching slot, the second latching hook engaged in the first latching slot, and the fixing member fixed in the fixing hole.

10. The electronic device of claim 9, wherein the supporting member comprises a supporting surface parallel to the side wall, and the fixing hole is defined in the supporting surface.

11. The electronic device of claim 10, wherein the first latching hook comprises a first main portion extending upward from the side wall of the housing, a first latching arm extending out from the distal end of the first main portion, and a first latching corner protrusion extending from the side edge of the first latching arm, and the first latching corner protrusion, the first latching arm and the distal end of the first main portion cooperatively define a first latching groove, the first latching corner protrusion engages in the second latching slot according to the first latching groove.

12. The electronic device of claim 11, wherein a distal end of the first latching corner protrusion is bent towards the second latching hook.

13. The electronic device of claim 12, the opening direction of the first latching slot is opposite to the bending direction of the first latching corner protrusion.

14. The electronic device of claim 11, wherein the second latching hook comprises a second main portion extending upward from the side wall of the housing, a second latching arm extending out from the distal end of the second main portion, and a second latching corner protrusion extending from the side edge of the second latching arm, and the second latching corner protrusion, the second latching arm and the distal end of the second main portion cooperatively define a second latching groove, the second latching corner protrusion engages in the first latching slot according to the second latching groove.

15. The electronic device of claim 14, wherein a distal end of the second latching corner protrusion is bent towards the inserting direction of the circuit board.

16. The electronic device of claim 15, the opening direction of the second latching slot is opposite to the bending direction of the first latching corner protrusion.

17. The electronic device of claim 14, wherein the length of the first main portion, the length of the second main portion and the distance from the supporting surface to the side wall are equal to each other, respectively.
